(19) United States
(12) Patent Application Publication
(10) Pub. No.: US 2009/0166813 A1
(43) Pub. Date: Jul. 2, 2009

(54) METHOD FOR MANUFACTURING SEMICONDUCTOR DEVICE AND SEMICONDUCTOR DEVICE

(75) Inventor: Yusuke MATSUZAWA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/342,122

(22) Filed: Dec. 23, 2008

(30) Foreign Application Priority Data
Dec. 28, 2007 (JP) 2007-340015

(51) Int. Cl. H01L 29/02; H01L 21/302; H01L 21/02

(52) U.S. Cl. 257/635; 438/702; 257/E21.002; 257/E27.001; 257/E29.002

(57) ABSTRACT

A method for manufacturing a semiconductor device includes forming a first semiconductor layer on a semiconductor substrate, forming a second semiconductor layer on the first semiconductor layer, etching the second semiconductor layer and the first semiconductor layer to form a first groove passing through the second semiconductor layer and the first semiconductor layer, forming a first support having tensile stress in the first groove, etching the second semiconductor layer to form a second groove that exposes the first semiconductor layer, forming a cavity between the second semiconductor layer and the semiconductor substrate by etching the first semiconductor layer through the second groove, forming an insulating film in the cavity, and forming a buried film having tensile stress in the second groove.

### BACKGROUND

1. Technical Field

The present invention relates to a method for manufacturing a semiconductor device and a semiconductor device, and more particularly to a technique for partially forming a so-called silicon-on-insulator (SOI) structure on a semiconductor substrate.

2. Related Art

Regarding a field-effect transistor (FET) formed on an SOI substrate, its usefulness is attracting attention in respects of ease of isolation, freedom from latch-up, and smallness of source/drain junction capacitance.

In particular, regarding a fully-depleted SOI transistor, which is easily driven at a low voltage due to its low power consumption and high speed operation, researches on the operation of an SOI transistor in a fully-depleted mode are actively performed.

For example, as an SOI substrate, a separation by implanted oxygen (SIMOX) substrate and a bonded substrate are used.

However, their manufacturing methods are both special, and therefore these substrates cannot be produced in a typical complementary metal oxide semiconductor (CMOS) process.

To overcome this disadvantage, there is known a method of separation by bonding silicon islands (SBSI) in which an SOI structure is produced from an ordinary bulk silicon wafer through a typical CMOS process.

For example, refer to T. Sakai et al., “Separation by Bonding Si Islands (SBSI) for LSI Application”, Second International SiGe Technology and Device Meeting, Meeting Abstract, pp. 230-231, May (2004).

The SBSI method will be described below with reference to the drawings.

FIGS. 11A to 13B show a method for manufacturing a semiconductor device according to an example of the related art.

Among FIGS. 11A to 13B, FIGS. 11A, 12A and 13A are plan views and FIGS. 11B, 12B and 13B are sectional views taken along the lines X11-X′11, X12-X′12 and X13-X′13 of FIGS. 11A, 12A and 13A, respectively.

As shown in FIGS. 11A and 11B, a film of a silicon germanium (SiGe) layer 111 and a film of a Si layer 113 are first formed in sequence on a silicon (Si) substrate 101, and grooves h′1 for a support are formed in the films.

The formation of the Si layer 113 and the SiGe layer 111 is performed by an epitaxial growth method, and the formation of the grooves h′1 for a support is performed by dry etching.

After a support film is formed over the entire surface of the Si substrate 101, the support film is dry etched, thereby forming a support 122 as shown in FIGS. 12A and 12B.

Further, the Si layer 113 and the SiGe layer 111 exposed below the support 122 are also dry etched.

In this condition, when the SiGe layer 111 is etched with a fluoro-nitric acid solution from the directions of arrows of FIG. 12A, a cavity 125 is formed under the Si layer 113 in the form where the Si layer 113 is hanging from the support 122.

Next, as shown in FIGS. 13A and 13B, the Si substrate 101 is thermally oxidized, thereby forming a silicon oxide (SiO₂) film 131 in the cavity 125 (oxidation process for a buried oxide (BOX)).

In this way, an SOI structure composed of the silicon oxide (SiO₂) film 131 and the Si layer 113 is formed on the bulk Si substrate (i.e., bulk silicon wafer) 101.

The SiO₂ film 131 is also referred to as a “BOX layer”, and the Si layer 113 is also referred to as an “SOI layer”.

After the formation of the SOI structure, a SiO₂ film (not shown) is formed over the entire surface of the Si substrate 101 by chemical vapor deposition (CVD).

The SiO2 film and the support 122 are then planarized by chemical mechanical polishing (CMP), and are wet etched with a hydrofluoric acid (HF) solution (i.e., HF etching), thereby exposing the surface of the Si layer 113.

As described above, the SBSI method is a very effective method in that a device formed in the SOI layer (hereinafter referred to as an “SOI device”) can be provided at a low cost, and that a device formed directly on a bulk Si substrate (hereinafter referred to as a “bulk Si device”) as well as the SOI device can easily be mounted together on the same substrate.

However, when an SOI device formed by the SBSI method and a typical SOI device formed from an SOI wafer are compared to each other, there is no difference between them in terms of performance.

Therefore, from the viewpoint of strengthening advantages of the SBSI method, it has been desired to improve the performance of the SOI device formed by the SBSI method by taking advantages of the structure unique to SBSI processes.

On the other hand, performance improvements, such as an increase in speed and a decrease in size, are achieved by advancing miniaturization in the current typical semiconductor devices.

However, such performance improvements due to miniaturization are close to the limit, and therefore a variety of enterprises and research institutions attempt to achieve improvements in device performance in ways other than miniaturization.

One of measures to improve performance is a technique to apply stress onto a region that will become a channel (hereinafter referred to as a “channel region”) so as to enhance mobility of carriers.

That is, there is a so-called strained Si channel technique.

For example, refer to Tsutomu Tezuka et al., “Fabrication and Electrical Characterization of Strained Si-on-insulator/Strained SiGe-on-insulator Dual Channel CMOS structures with High-Mobility Channels”, IEEJ Transactions on Electronics, Information and Systems, Vol. 126 (2006), No. 11, pp. 1332-1339.

The strained Si channel technique is roughly divided into global strain techniques as exemplified in SiGe on insulator (SGOI) and strained Silicon on insulator (SSOI) and local strain techniques using a nitride film and so on.

It is a fact generally known that, as shown in FIG. 14A, when tensile stresses are provided in a direction substantially in parallel to the channel in plan view (hereinafter referred to as a “channel parallel direction”) and tensile stresses are provided in a direction substantially vertical to the channel in plan view (hereinafter referred to as a “channel vertical direction”), mobility of electrons is enhanced.

It is also the foregoing fact that, as shown in FIG. 14B, when compressive stresses are provided in the channel parallel direction and when tensile stresses are provided in the channel vertical direction, mobility of holes is enhanced.

For example, refer to A. V-Y. Thean et al., “Uniaxial-Biaxial Stress Hybridization For Super-Critical Strained-Si Directly On Insulator (SC-SSOI) PMOS With Different Channel Orientation”, IEDM 05-515.

As shown in FIGS. 11A to 13B, the SBSI method has unique processes such as a process of forming a support, a process of forming a cavity, and a process of filling the cavity.

In an SOI device formed by such processes (hereinafter referred to as an “SBSI device”), the SOI layer is partially (i.e., island-like) formed in plan view.

Strain techniques in the related art, such as SGOI and SSOI, cannot therefore be applied to the SBSI method.

There has not been achieved an SBSI device (i.e., an SOI device formed by an SBSI method) in which strain is provided in the channel region to enhance the mobility of electrons.

### SUMMARY

An advantage of the present invention is to provide a method for manufacturing a semiconductor device and a semiconductor device that enable achievement of an SBSI device with enhanced mobility of majority carriers.

A method for manufacturing a semiconductor device according to a first aspect of the invention includes forming a first semiconductor layer on a semiconductor substrate, forming a second semiconductor layer on the first semiconductor layer, etching the second semiconductor layer and the first semiconductor layer to form a first groove passing through the second semiconductor layer and the first semiconductor layer, forming a first support having tensile stress in the first groove, etching the second semiconductor layer to form a second groove that exposes the first semiconductor layer, forming a cavity between the second semiconductor layer and the semiconductor substrate by etching the first semiconductor layer through the second groove, forming an insulating film in the cavity, and forming a buried film having tensile stress in the second groove.

It is preferable that the foregoing method according to the first aspect of the invention further include forming a first gate electrode on the second semiconductor layer with a first gate insulating film interposed therebetween.

The “semiconductor substrate” according to the invention means, for example, a bulk silicon (Si) substrate, the “first semiconductor layer” means, for example, a single-crystal silicon germanium (SiGe) layer, and the “second semiconductor layer” means, for example, a single-crystal Si layer.

The SiGe layer and the Si layer can be formed, for example, by an epitaxial growth method.

The “first support” and “buried film” according to the invention are each made of an insulating film, such as a silicon oxide (SiO₂) film or a silicon nitride (Si₃N₄) film.

By the foregoing method according to the first aspect of the invention, the first support having tensile stress is formed adjacent to the side surface of the second semiconductor layer.

This enables the second semiconductor layer to be provided with forces pulling the layer (i.e., tensile stress) towards the outside.

Also, the buried film having tensile stress is formed adjacent to the side surface of the second semiconductor layer.

This enables the second semiconductor layer to be provided with tensile stress.

Accordingly, for example, the second semiconductor layer in a region where an NMOS transistor is to be formed can be provided with tensile stress in the channel parallel direction and tensile stress in the channel vertical direction.

Providing such stress enables the second semiconductor layer in the channel region to have strain, improving mobility of electrons.

A method for manufacturing a semiconductor device according to a second aspect of the invention includes (a) forming a first semiconductor layer on a semiconductor substrate, (b) forming a second semiconductor layer on the first semiconductor layer, (c) etching the second semiconductor layer and the first semiconductor layer to form a first groove passing through the second semiconductor layer and the first semiconductor layer, (d) forming a second support having compressive stress in the first groove, (e) etching the second semiconductor layer to form a second groove that exposes the first semiconductor layer, (f) forming a cavity between the second semiconductor layer and the semiconductor substrate by etching the first semiconductor layer through the second groove, (g) forming an insulating film in the cavity, and (h) forming a buried film having tensile stress in the second groove.

It is preferable that the foregoing method according to the second aspect of the invention further include (i) forming a second gate electrode on the second semiconductor layer with a second gate insulating film interposed therebetween. In step (i), the second gate electrode is disposed such that a direction in which a force acts from the second support to the second semiconductor layer substantially coincides with a channel parallel direction and a direction in which a force acts from the buried film to the second semiconductor layer substantially coincides with a channel vertical direction.

By the foregoing method according to the second aspect of the invention, forming the second support having compressive stress is formed adjacent to the side surface of the second semiconductor layer.

This enables the second semiconductor layer to be provided with forces compressing the layer (i.e., compressive stress) towards the inside.

Also, the buried film having tensile stress is formed adjacent to the side surface of the second semiconductor layer.

This enables the second semiconductor layer to be provided with tensile stress.

Accordingly, for example, the second semiconductor layer in a region where a PMOS transistor is to be formed can be provided with compressive stress in the channel parallel direction and tensile stress in the channel vertical direction.

Providing such stress enables the second semiconductor layer in the channel region to have strain, improving mobility of holes.

A method for manufacturing a semiconductor device according to a third aspect of the invention includes (a) forming a first semiconductor layer on a semiconductor substrate having a first region in which an NMOS transistor is to be formed and a second region in which a PMOS transistor is to be formed, (b) forming a second semiconductor layer on the first semiconductor layer, (c) etching the second semiconductor layer and the first semiconductor layer to form first grooves around the first region and around the second region, the first grooves passing through the second semiconductor layer and the first semiconductor layer, (d) forming a first support having tensile stress in the first groove formed around the first region, (e) forming a second support having compressive stress in the first groove formed around the second region, (f) etching the second semiconductor layer to form, around the first region and around the second region, second grooves that expose the first semiconductor layer, (g) forming cavities between the second semiconductor layer in the first region and the second semiconductor layer and between the semiconductor substrate in the second region and the second semiconductor layer by etching the first semiconductor layer through the second grooves, (h) forming an insulating film in the cavity formed in the first region and in the cavity formed in the second region, and (i) forming a buried film having tensile stress in the second groove formed around the first region and in the second groove formed around the second region.

It is preferable that the forgoing method according to the third aspect of the invention further include (j) forming a first gate electrode on the second semiconductor layer in the first region with a first gate insulating film interposed therebetween, and (k) forming a second gate electrode on the second semiconductor layer in the second region with a second gate insulating film interposed therebetween. In step (k), the second gate electrode is disposed such that a direction in which a force acts from the second support to the second semiconductor layer substantially coincides with a channel parallel direction and a direction in which a force acts from the buried film to the second semiconductor layer substantially coincides with a channel vertical direction.

By the foregoing method according to the third aspect of the invention, the first support having tensile stress is formed adjacent to the side surface of the second semiconductor layer in the first region.

This enables the second semiconductor layer in the first region to be provided with tensile stress.

Also, the buried film having tensile stress is formed adjacent to the side surface of the second semiconductor layer in the first region.

This enables the second semiconductor layer in the first region to be provided with tensile stress.

Accordingly, the second semiconductor layer in the first region can be provided with tensile stress in the channel parallel direction and tensile stress in the channel vertical direction.

Providing such stress enables the second semiconductor layer in the first region to have strain, improving mobility of electrons.

Similarly, the second support having compressive stress is formed adjacent to the side surface of the second semiconductor layer in the second region.

This enables the second semiconductor layer in the second region to be provided with compressive stress.

Also, the buried film having tensile stress is formed adjacent to the side surface of the second semiconductor layer in the second region.

This enables the second semiconductor layer in the second region to be provided with tensile stress.

Accordingly, the second semiconductor layer in the second region can be provided with compressive stress in the channel parallel direction and tensile stress in the channel vertical direction.

Providing such stress enables the second semiconductor layer in the second region to have strain, improving mobility of holes.

As such, it is possible to achieve an SBSI device having an NMOS transistor in which strain is provided to the second semiconductor layer in the channel region to improve the mobility of electrons and the PMOS transistor in which strain is provided to the second semiconductor layer in the channel region to improve the mobility of holes.

In the foregoing method according to the second aspect of the invention, it is preferable that step (d) include forming a support film having tensile stress on the semiconductor substrate so as to fill the first groove, and ion implanting an impurity into the support film.

Here, forces that the support film has are changed from tensile stress to compressive stress, for example, by ion implanting an impurity into the support film.

By the foregoing method according to the second aspect of the invention, the first support having tensile stress and the second support having compressive stress can be formed by the same support film.

This can contribute to reduction of manufacturing processes.

A semiconductor device according to a fourth aspect of the invention includes a semiconductor substrate, an insulating film formed on the semiconductor substrate, a semiconductor layer formed on the insulating film, and an insulating layer formed on the semiconductor substrate so as to surround the semiconductor layer in plan view, the insulating layer having tensile stress.

With such a configuration, the second semiconductor layer can be provided with tensile stress in the channel parallel direction and tensile stress in the channel vertical direction.

A semiconductor device according to a fifth aspect of the invention includes a semiconductor substrate, an insulating film formed on the semiconductor substrate, a semiconductor layer formed on the insulating film, and an insulating layer formed on the semiconductor substrate so as to surround the semiconductor layer in plan view.

The insulating layer includes a first insulating layer disposed on sides before and after the semiconductor layer toward one direction in plan view and a second insulating layer disposed on sides before and after the semiconductor layer toward another direction substantially vertically intersecting the one direction in plan view.

The first insulating layer has compressive stress and the second insulating layer has tensile stress.

The “one direction” as used herein is, for example, a channel parallel direction, and the “other direction” is, for example, a channel vertical direction.

With the semiconductor device according to the fifth aspect of the invention, for example, the second semiconductor layer can be provided with compressive stress in the channel parallel direction and tensile stress in the channel vertical direction.

### BRIEF DESCRIPTION OF THE DRAWINGS

The invention will be described with reference to the accompanying drawings, wherein like numbers reference like elements.

FIGS. 1A to 1D show a method for manufacturing a semiconductor device according to a first embodiment (first drawings)

FIGS. 2A to 2D show the method for manufacturing a semiconductor device according to the first embodiment (second drawings).

FIGS. 3A to 3D show the method for manufacturing a semiconductor device according to the first embodiment (third drawings).

FIGS. 4A to 4D show the method for manufacturing a semiconductor device according to the first embodiment (fourth drawings).

FIGS. 5A to 5D show the method for manufacturing a semiconductor device according to the first embodiment (fifth drawings).

FIGS. 6A to 6D show the method for manufacturing a semiconductor device according to the first embodiment (sixth drawings).

FIGS. 7A to 7D show the method for manufacturing a semiconductor device according to the first embodiment (seventh drawings).

FIGS. 8A to 8D show the method for manufacturing a semiconductor device according to the first embodiment (eighth drawings).

FIGS. 9A to 9D show a method for manufacturing a semiconductor device according to a second embodiment (first drawings).

FIGS. 10A to 10D show the method for manufacturing a semiconductor device according to the second embodiment (second drawings).

FIGS. 11A and 11B show a method for manufacturing a semiconductor device according to an example of the related art (first drawings).

FIGS. 12A and 12B show the method for manufacturing a semiconductor device according to the example of the related art (second drawings).

FIGS. 13A and 13B show the method for manufacturing a semiconductor device according to the example of the related art (third drawings).

FIGS. 14A and 14B show directions of stress for improving mobility.

### DESCRIPTION OF EXEMPLARY EMBODIMENTS

Embodiments of the invention will be described below with reference the accompanying drawings.

### First Embodiment

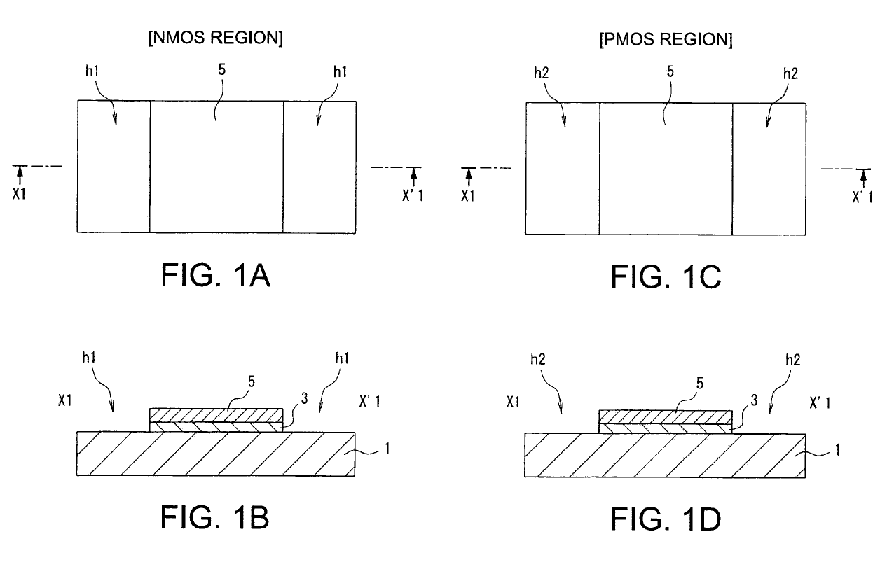

FIGS. 1A to 8D show a method for manufacturing a semiconductor device of the first embodiment of the invention.

Among FIGS. 1A to 8D, FIGS. 1A to 8A and FIGS. 1B to 8B show a first region in which an NMOS transistor is to be formed and an isolation region that surrounds the first region in plan view (hereinafter these regions are collectively referred to as an “NMOS region”).

FIGS. 1A to 8A are plan views, and FIGS. 1B to 8B are sectional views taken along the line X1-X′1 to X8-X′8 of FIGS. 1A to 8A, respectively.

Among FIGS. 1A to 8D, FIGS. 1C to 8C and FIGS. 1D to 8D show a second region in which a PMOS transistor is to be formed and an isolation region that surrounds the second region in plan view (hereinafter these regions are collectively referred to as a “PMOS region”).

FIGS. 1C to 8C are plan views, and FIGS. 1D to 8D are sectional views taken along the line X1-X′1 to X8-X′8 of FIGS. 1C to 8C, respectively.

As shown in FIGS. 1A to 1D, a single-crystal silicon germanium (SiGe) layer 3 is first formed on a bulk silicon (Si) substrate 1 having the NMOS region and the PMOS region, and a single-crystal Si layer 5 is formed on the SiGe layer 3.

The SiGe layer 3 and the Si layer 5 are continuously formed, for example, by an epitaxial growth method.

Next, the Si layer 5 and the SiGe layer 3 are partially etched by a photolithography technique and an etching technique.

Thus, support holes h1 with the Si substrate 1 serving as the bottom surfaces are formed in the NMOS region, and support holes h2 with the Si substrate 1 serving as the bottom surfaces are formed in the PMOS region.

The support holes h1 and h2 are formed in an area overlapping the isolation region in plan view.

Note that, in this etching process, etching may be stopped at the surface of the Si substrate 1, and the Si substrate 1 may also be overetched to form a recess.

A first support film is next formed on the Si substrate 1 in such a manner as to fill the support holes h1 and h2.

This support film is an insulating film having tensile stress, such as a SiO₂ film having tensile stress or a silicon nitride (Si₃N₄) film having tensile stress.

The SiO₂ film having tensile stress can be formed, for example, by a plasma tetraethoxysilane (TEOS) method in which the flow rate ratio of a TEOS source to ozone or oxygen is high.

The Si₃N₄ film having tensile stress can be formed, for example, by low-pressure CVD (LPCVD).

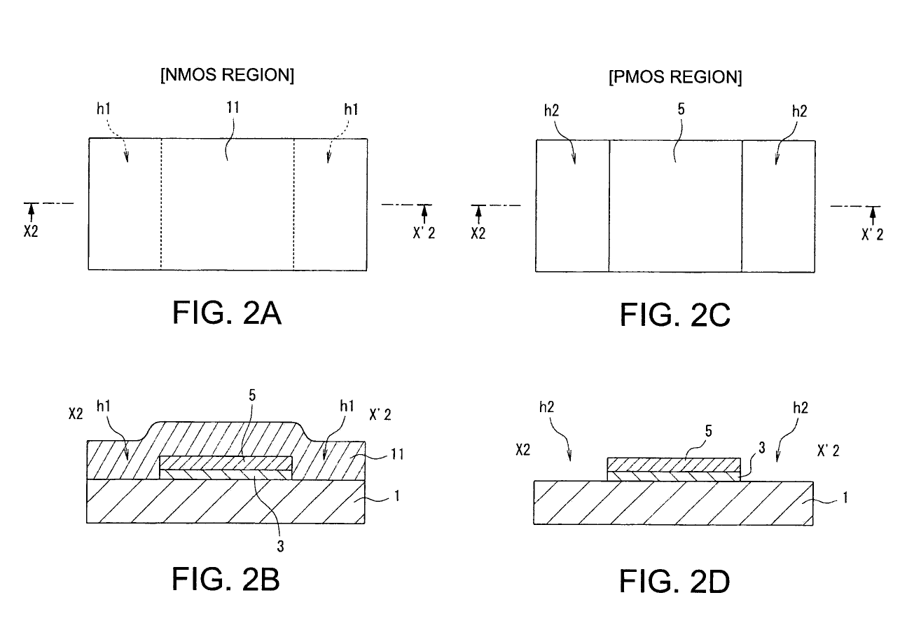

Next, as shown in FIGS. 2A to 2D, the support film 11 having tensile stress is partially etched by a photolithography technique and an etching technique.

Thus, the support film 11 is left behind on the Si substrate 1 in the NMOS region, and the support film 11 is removed from the Si substrate 1 in the PMOS region.

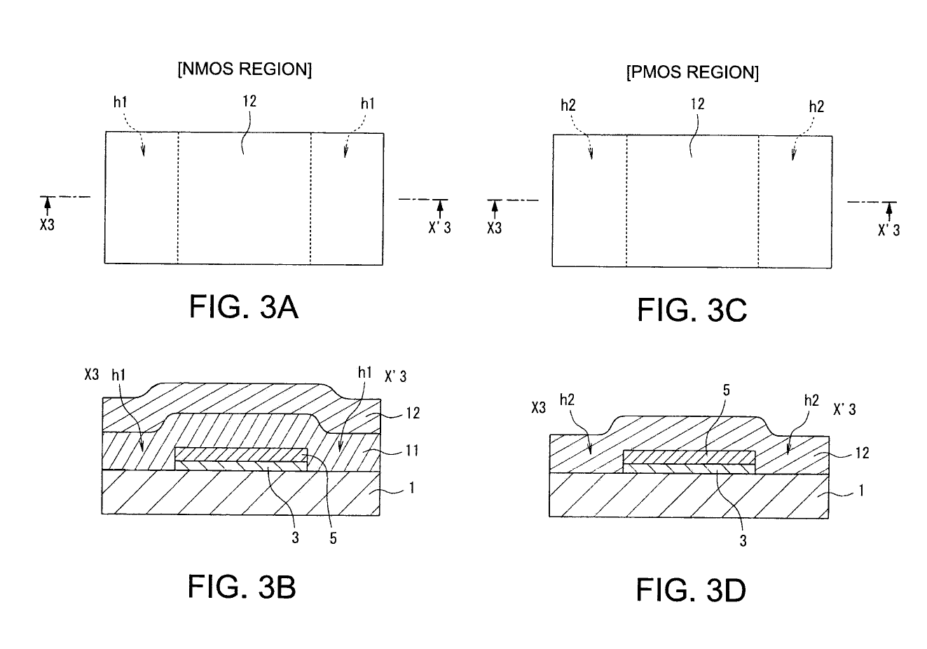

Next, as shown in FIGS. 3A to 3D, a second support film 12 is formed on and above the Si substrate 1.

This support film 12 is an insulating film having compressive stress, such as a SiO₂ film having compressive stress or a Si₃N₄ film having compressive stress.

The SiO₂ film having compressive stress can be formed, for example, by the plasma TEOS method in which the flow rate ratio of a TEOS source to ozone or oxygen is low.

The Si₃N₄ film having compressive stress can be formed, for example, by plasma-enhanced CVD (PECVD).

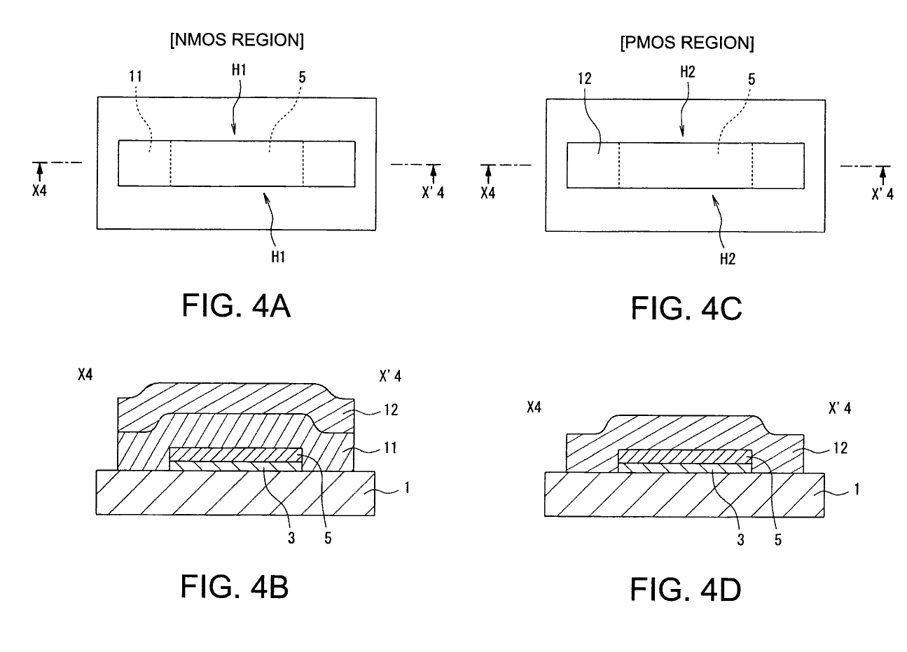

Next, as shown in FIGS. 4A to 4D, the support films 11 and 12 and the SiGe layers 3 are partially etched in sequence by a photolithography technique and an etching technique.

Thus, in the NMOS region, a support is formed from the support film 11 and grooves H1 with the Si substrate 1 serving as the bottom surfaces are formed in an area overlapping the isolation region in plan view.

The Si layer 5 after etching is rectangular in plan view such that its short side surfaces are in contact with the support 11 having tensile stress and its long side surfaces face the grooves H1.

In the PMOS region, a support is formed from the support film 12 and grooves H2 with the Si substrate 1 serving as the bottom surfaces are formed in an area overlapping the isolation region in plan view.

The Si layer 5 after etching is rectangular in plan view such that its short side surfaces are in contact with the support 12 having compressive stress and its long side surfaces face the grooves H2.

Note that, in the foregoing etching process, etching may be stopped at the surface of the Si substrate 1, and the Si substrate 1 may also be overetched to form a recess.

Next, a fluoro-nitric acid solution, for example, is brought into contact with side surfaces of each of the Si layers 5 and the SiGe layers 3 through the grooves H1 and H2, so that the SiGe layers 3 are selectively etched and removed.

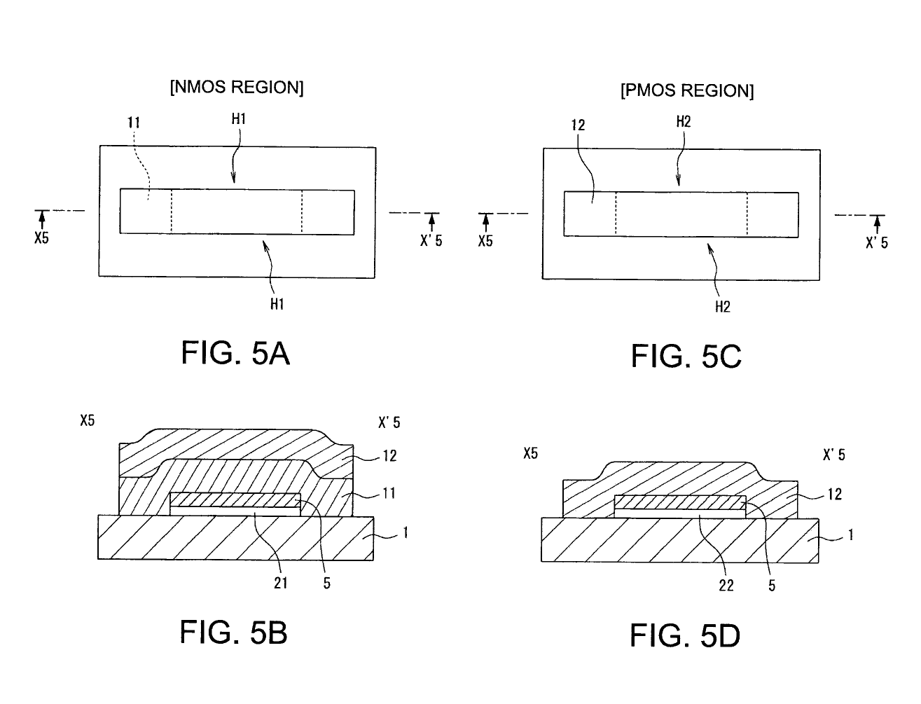

In this way, as shown in FIGS. 5A to 5D, a cavity 21 is formed between the Si substrate 1 and the Si layer 5 in the NMOS region, and a cavity 22 is formed between the Si substrate 1 and the Si layer 5 in the PMOS region.

In wet etching using a fluoro-nitric acid solution, the etching rate of SiGe is greater than that of Si (i.e., high etching selectivity to Si), allowing only the SiGe layer to be removed by etching while leaving behind the Si layer 5.

After the formation of the cavity, the Si layer 5 in the NMOS region is supported by the support 11 and the Si layer 5 in the PMOS region is supported by the support 12.

Note that, in the foregoing etching process, fluorine nitrate/hydrogen peroxide mixture, ammonia/hydrogen peroxide mixture, or fluorine acetate/hydrogen peroxide mixture may be used instead of the fluoro-nitric acid solution.

In this case, the etching rate of SiGe is greater than that of Si, allowing the SiGe layers to be selectively removed.

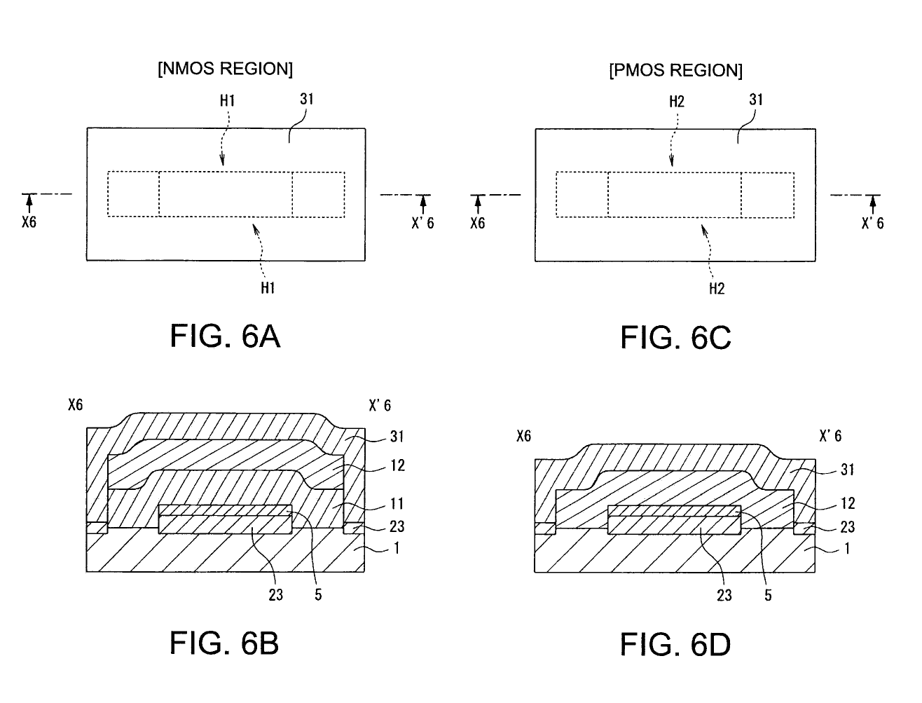

Next, as shown in FIGS. 6A to 6D, a SiO₂ film 23 in the cavity of the NMOS region and the SiO₂ film 23 in the cavity of the PMOS region are formed, for example, by thermal oxidation.

At this point, the surface of the Si substrate 1 facing the inside of each of cavities of the NMOS region and the PMOS region and the back surface of each of the Si layers 5 are thermally oxidized to cause the SiO₂ films 23 to grow, so that the SiO₂ films 23 growing from the top and the bottom are brought into close contact with each other around the center of each cavity.

Thus, the inside of each cavity of the NMOS region and the PMOS region is buried with the SiO₂ film 23.

After the SiO₂ film 23 is formed, a buried film 31 is formed on the Si substrate 1 to fill the grooves H1 in the NMOS region and the grooves H2 in the PMOS region.

The buried film 31 is an insulating film having tensile stress, such as a SiO₂ film having tensile stress or a Si₃N₄ film having tensile stress.

The SiO₂ film having tensile stress can be formed, for example, by the plasma TEOS method in which the flow rate ratio of a TEOS source to ozone or oxygen is high.

The Si₃N₄ film having tensile stress can be formed, for example, by LPCVD.

Next, the buried film 31 and the supports (film) 12 and 11 are removed while being planarized, for example, by CMP.

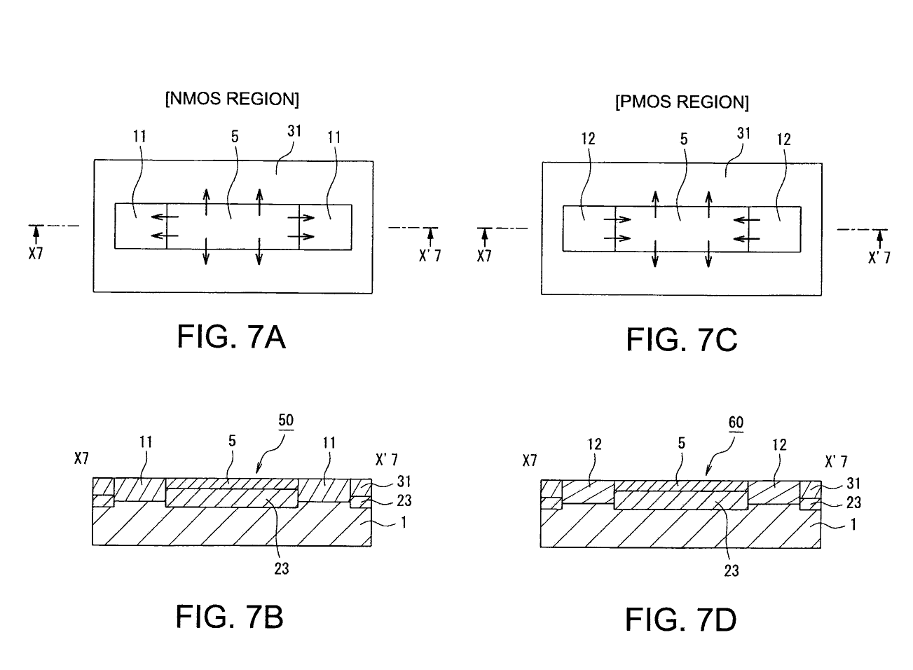

Wet etching using a hydrofluoric (HF) acid solution is further performed, as necessary, to expose the surfaces of the Si layers 5 as shown in FIGS. 7A to 7D.

Thus, an SOI structure 50 composed of the SiO₂ film (i.e., BOX layer) 23 and the Si layer (i.e., SOI layer) 5 is completed on the Si substrate 1 in the NMOS region and an SOI structure 60 composed of the SiO₂ film (i.e., BOX layer) 23 and the Si layer (i.e., SOI layer) 5 on the Si substrate 1 in the PMOS region is completed.

As shown in FIGS. 7A and 7B, in the SOI structure 50 in the NMOS region, its short side surfaces of the Si layer 5 are in contact with the supports 11 having tensile stress, and its long side surfaces are in contact with the buried film 31 having tensile stress.

Therefore, as indicated by arrows of FIG. 7A, the Si layer 5 is provided with forces pulling the layer (i.e., tensile stress) from its short sides towards the outside, and is provided with tensile stress from the long sides of the layer towards the outside.

That is, the supports 11 and the buried film 31 each function as a measure for imparting tensile stress to the Si layer 5.

The supports 11 and the buried film 31 surround the SOI structure 50 in plan view, functioning also as isolation layers.

On the other hand, in the SOI structure 60 in the PMOS region as shown in FIGS. 7C and 7D, the short side surfaces of the Si layer 5 are in contact with the supports 12 having tensile stress, and its long side surfaces are in contact with the buried film 31 having tensile stress.

Therefore, as indicated by arrows of FIG. 7C, the Si layer 5 is provided with forces pulling the layer (i.e., tensile stress) from its short sides towards the inside, and is provided with tensile stress from the long sides of the layer towards the outside.

That is, the supports 12 function as measures for imparting compressive stress to the Si layer 5, and the buried film functions as a measure for imparting tensile stress to the Si layer 5.

The supports 12 and the buried film 31 surround the SOI structure 60 in plan view, functioning also as isolation layers.

In the subsequent processes, an NMOS transistor is formed in the Si layer 5 in the NMOS region, and a PMOS transistor is formed in the Si layer 5 in the PMOS region.

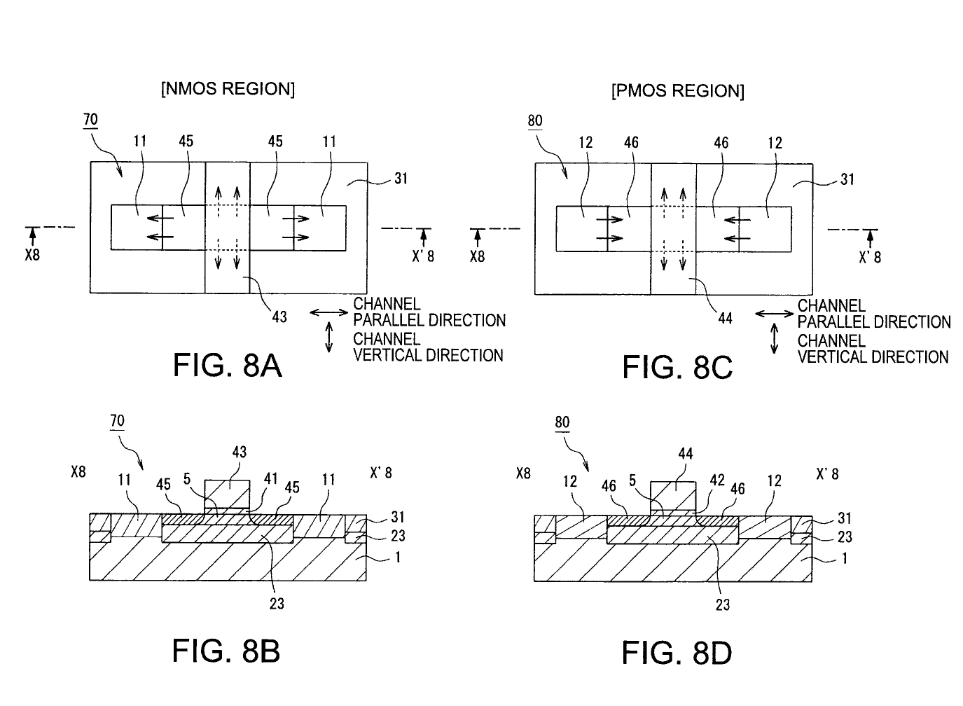

That is, as shown in FIGS. 8A to 8D, a gate insulating film 41 is formed on the surface of the Si layer 5 in the NMOS region, and a gate insulating film 42 is formed on the surface of the Si layer 5 in the PMOS region.

The gate insulating films 41 and 42 are, for example, a silicon oxide film (SiO₂) or a silicon oxynitride film (SiON) formed by thermal oxidation, or a High-K material film.

The gate insulating films 41 and 42 may be concurrently formed, or may be separately formed.

Next, a polycrystalline silicon (poly-Si) film is formed on the gate insulating films 41 and 42.

Formation of the polycrystalline silicon film is performed, for example, by a CVD method.

At this point, an impurity is introduced into the polycrystalline silicon film by ion implantation, in-Situ or the like to provide a polycrystalline silicon film with conductivity.

Specifically, a p-type impurity is ion implanted into the polycrystalline silicon film in the PMOS region under a condition where the entire NMOS region is covered with photo resist, and then an n-type impurity is ion implanted into the polycrystalline silicon film in the NMOS region under a condition where the entire PMOS region is covered with photo resist.

Thereafter, the entire Si substrate 1 is subjected to a heat treatment, so that the p-type impurity and the n-type impurity are concurrently diffused.

This enables the polycrystalline silicon film in the NMOS region to be provided with n-type conductivity and the polycrystalline silicon film in the PMOS region to be provided with p-type conductivity.

Next, the polycrystalline silicon film is partially etched by a photolithography technique and an etching technique.

Thus, a gate electrode 43 is formed on the gate insulating film 41 in the NMOS region and a gate electrode 44 is formed on the gate insulating film 42 in the PMOS region.

Note that, at this point, the gate electrode 43 is disposed such that a direction in which forces act from the supports 11 to the Si layer 5 coincides with the channel parallel direction and a direction in which forces act from the buried film 31 to the Si layer coincides with the channel vertical direction in the NMOS region.

Similarly, in the PMOS region, the gate electrode 44 is disposed such that a direction in which forces act from the supports 12 to the Si layer 5 coincides with the channel parallel direction and a direction in which forces act from the buried film 31 to the Si layer 5 coincides with the channel vertical direction.

Next, an impurity is ion implanted into the Si layer 5 with the gate electrodes 43 and 44 serving as masks and a heat treatment is performed to form an n-type source or drain (hereinafter referred to as an “S/D layer”) 45 in the Si layer 5 in the NMOS region and form a p-type S/D layer 46 in the Si layer 5 in the PMOS region.

Specifically, a p-type impurity is ion implanted into the Si layer 5 in the PMOS region under a condition where the entire NMOS region is covered with photo resist, and then an n-type impurity is ion implanted into the Si layer 5 in the NMOS region under a condition where the entire PMOS region is covered with photo resist.

Thereafter, the entire Si substrate 1 is subjected to a heat treatment, so that the p-type impurity and the n-type impurity are concurrently diffused.

This enables the n-type S/D layer 45 to be formed in the Si layer 5 in the NMOS region and the p-type S/D layer 46 to be formed in the Si layer 5 in the PMOS region.

Next, an interlayer insulting film (not shown) is formed, and this interlayer insulting film is partially etched to form first contact holes (not shown) having the gate electrodes 43 and 44 serving as the bottom surfaces and second contact holes (not shown) having the S/D layers 45 and 46 serving as the bottom surfaces.

Al wiring, plug electrodes or the like is formed inside the contact holes.

In this way, an NMOS transistor 70 is completed in the Si layer 5 in the NMOS region, and a PMOS transistor 80 is completed in the Si layer 5 in the PMOS region.

Thus, according to the first embodiment of the present invention, the supports 11 and the buried film 31 having tensile stress are formed adjacent to the side surfaces of the Si layer 5 in the NMOS region, providing tensile stress to the Si layer 5.

Accordingly, as shown in FIG. 8A, the Si layer 5 in the NMOS region can be provided with tensile stress along the channel parallel direction and tensile stress along the channel vertical direction.

The supports 12 having compressive stress and the buried film 31 having tensile stress are formed adjacent to the side surfaces of the Si layer 5 in the PMOS region, providing tensile stress to the Si layer 5.

Accordingly, as shown in FIG. 8C, the Si layer 5 in the PMOS region can be provided with compressive stress along the channel parallel direction and tensile stress along the channel vertical direction.

As such, it is possible to achieve an SBSI device having the NMOS transistor 70 in which strain is provided to the Si layer 5 in the channel region to enhance the mobility of electrons and the PMOS transistor 80 in which strain is provided to the Si layer 5 in the channel region to enhance the mobility of holes.

### Second Embodiment

In the foregoing first embodiment, the case of separately forming the supports 11 having tensile stress and the supports 12 having compressive stress has been described.

However, the formation method of the supports 11 and 12 is not limited to this case.

The present inventor has found that stress characteristics of an insulating film can be changed by ion implanting of an impurity into the insulating film.

Using this phenomenon, for example, the supports 11 and 12 of two kinds that differ in stress characteristics may be formed from a single insulating film.

That is, the present inventor has found that when each impurity of P+, As+, Sb+ and BF2+ is ion implanted into the Si₃N₄ film having tensile stress at the stage immediately after film formation (As DEPO), the stress characteristics of the film changes from the tensile stress to the compressive stress.

In the case where lamp annealing (e.g., at 1040° C., for 10 seconds) is performed after the Si₃N₄ film is ion implanted, it is found that compressive stress is maintained in samples except for P+.

In the second embodiment, a case of forming the supports 11 and 12 using the foregoing phenomenon will be described.

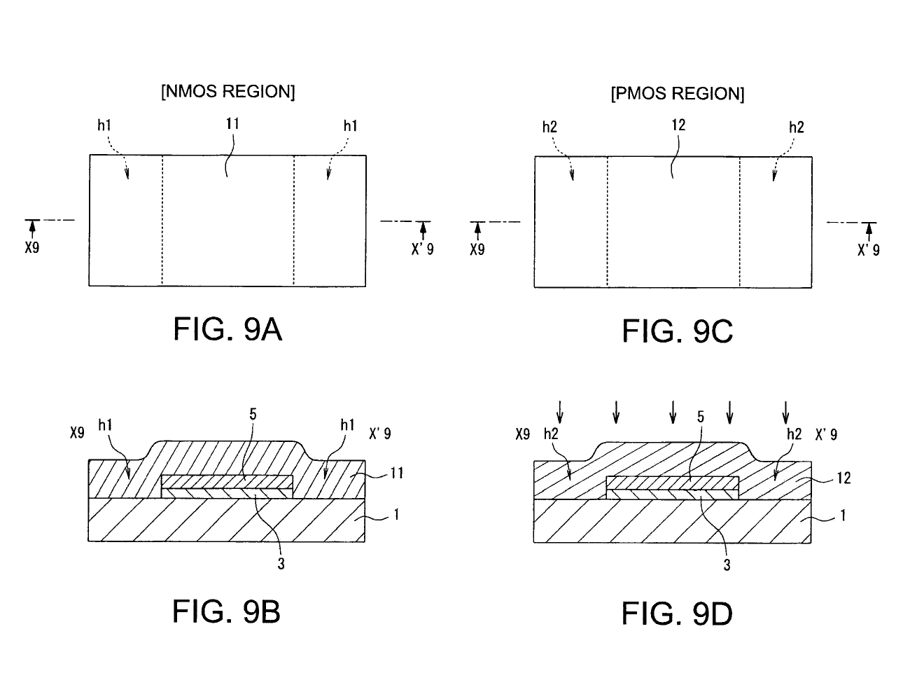

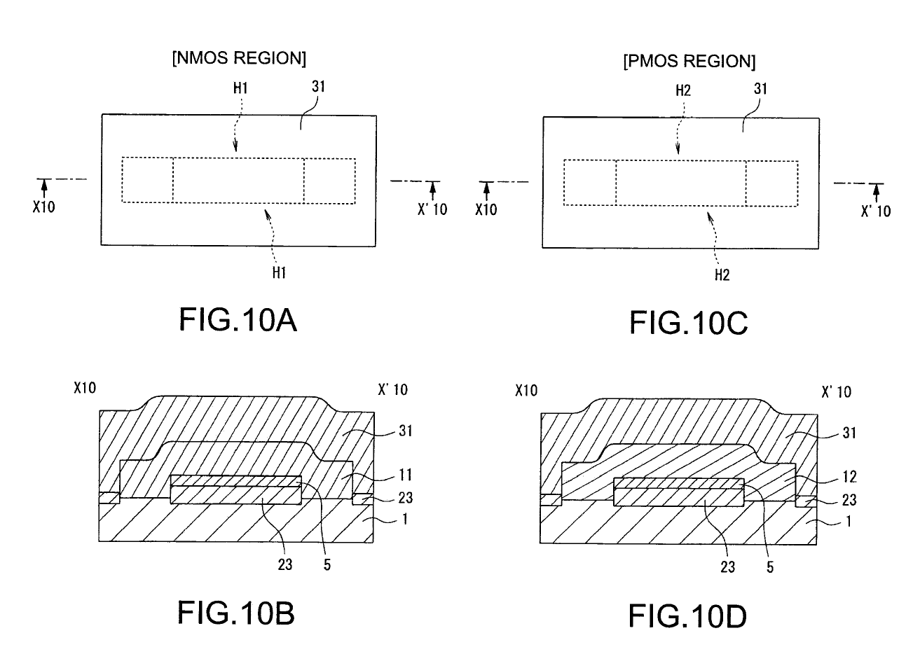

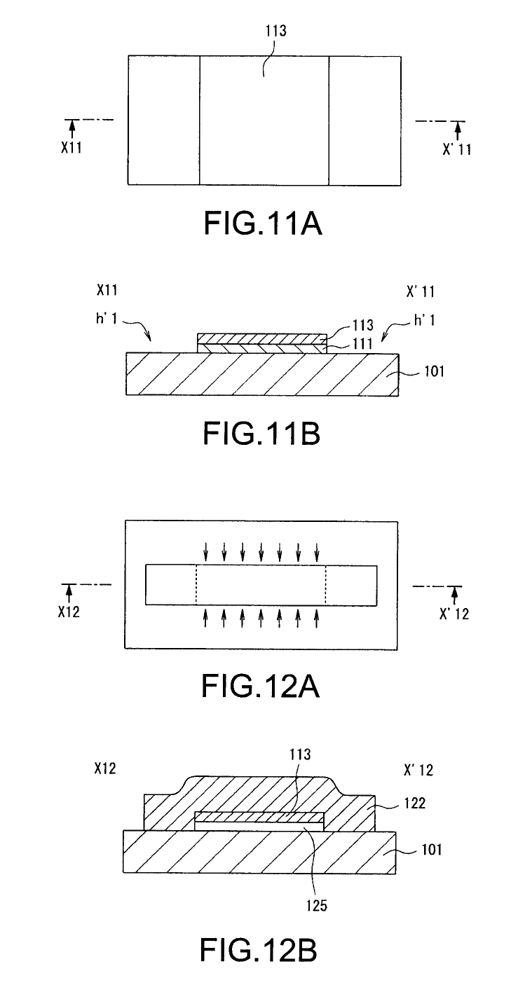

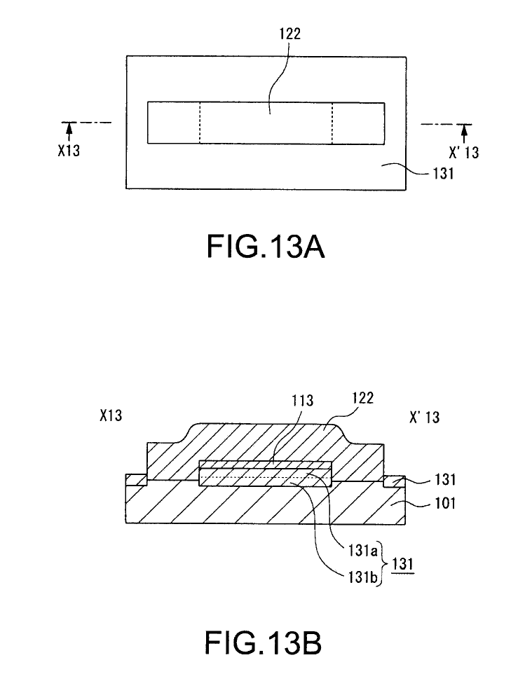

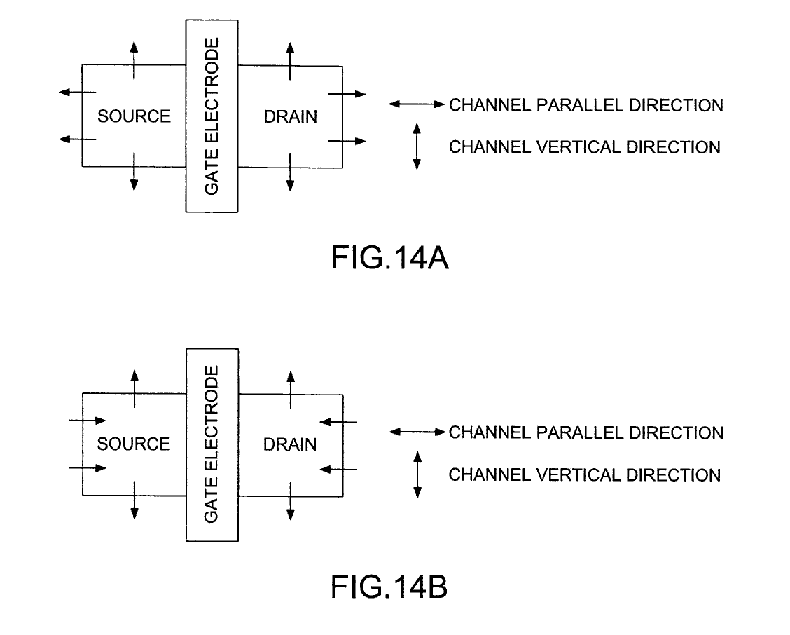

FIGS. 9A to 10D show a method for manufacturing a semiconductor device according to the second embodiment of the present invention.

Among FIGS. 9A to 10D, FIGS. 9A and 10A and FIGS. 9B and 10B show an NMOS region.

FIGS. 9A to 10A are plan views, and FIGS. 9B to 10B are sectional views taken along the line X9-X′9 and X10-X′10 of FIGS. 9A and 10A, respectively.

FIGS. 9C and 10C and FIGS. 9D and 10D show a PMOS region.

FIGS. 9C and 10C are plan views, and FIGS. 9D and 10D are sectional views taken along the line X9-X′9 and X10-X′10 of FIGS. 9C and 10C, respectively.

Note that in FIGS. 9A to 10D, parts having the same configurations as those in FIGS. 1A to 8D are indicated by the same reference characters and their detailed description is omitted.

With reference to FIGS. 9A to 9D, processes up to a process of forming the support film 11 having tensile stress on the Si substrate 1 are the same as those in the first embodiment.

The support film 11 is an insulating film having compressive stress, such as a SiO₂ film having compressive stress or a Si₃N₄ film having tensile stress.

With reference to FIGS. 9A to 9D, after the SiO₂ film is formed, a resist pattern (not shown) for covering the NMOS region and exposing the PMOS region is formed on the support film 11.

This formation of the resist pattern is performed, for example, by a photolithography technique.

Next, an impurity is ion implanted into the support film 11 with the foregoing resist pattern serving as a mask.

Here, for example, arsenic (As+) or antimony (Sb+) is ion implanted into the support film 11.

The impurity is ion implanted only into the support film 11 in the PMOS region, enabling its stress characteristics to be changed from tensile stress to compressive stress.

That is, the support film 12 having compressive stress can be formed from the support film 11 having tensile stress.

The subsequent processes are the same as those in the first embodiment.

That is, the grooves H1 and H2 (refer to FIGS. 4A to 4D) are formed in each of the NMOS region and the PMOS region, and the SiGe layer 3 is removed through the grooves H1 and H2.

Thus, the cavities 21 and 22 (refer to FIGS. 5A to 5D) are formed in the NMOS region and in the PMOS region.

Next, the SiO₂ film 23 (refer to FIGS. 6A to 6D) is formed in each of the cavities 21 and 22.

As shown in FIGS. 10A to 10D, the buried film 31 having tensile stress is formed on the Si substrate 1 to fill the grooves H1 and H2.

Next, the buried film 31 and the supports (support films) 11 and 12 are removed while being planarized, for example, by CMP.

Wet etching using a hydrofluoric (HF) acid solution is further performed, as necessary, to expose the surface of the Si layer 5 as shown in FIGS. 7A to 7D.

Thus, the SOI structure 50 composed of the SiO₂ film (i.e., BOX layer) 23 and the Si layer (i.e., SOI layer) 5 is completed on the Si substrate 1 in the NMOS region and the SOI structure 60 composed of the SiO₂ film (i.e., BOX layer) 23 and the Si layer (i.e., SOI layer) 5 on the Si substrate 1 in the PMOS region is completed.

Thereafter, as shown in FIGS. 8A to 8D, the NMOS transistor 70 is formed on the Si layer 5 in the NMOS region, and the PMOS transistor 80 is formed on the Si layer 5 in the PMOS region.

In this way, according to the second embodiment in the invention, the same effects as those in the first embodiment can be obtained.

Furthermore, as compared to the first embodiment, the supports 11 having tensile stress and the supports 12 having compressive stress can be formed from a single insulating film, enabling one film formation process and one etching process to be omitted.

Accordingly, this can contribute to reduction of manufacturing processes.

In the foregoing first and second embodiments, the SiGe layer 3 corresponds to the “first semiconductor layer” of the invention, and the Si layer 5 corresponds to the “second semiconductor layer” of the invention.

The support 11 corresponds to the “first support” of the invention, and the support 12 corresponds to the “second support” of the invention.

Further, the support holes h1 and h2 correspond to the “first grooves” of the invention, and the grooves H1 and H2 correspond to the “second grooves” of the invention.

The SiO₂ film 23 corresponds to an “insulating film” of the invention.

Further, the gate insulating film 41 corresponds to the “first gate insulating film” of the invention, and the gate insulating film 42 corresponds to the “second gate insulating film” of the invention.

The gate electrode 43 corresponds to the “first gate electrode” of the invention, and the gate electrode 44 corresponds to the “second gate electrode” of the invention.

Further, the supports 11 and the buried film 31 left behind in the NMOS region and the supports 12 and the buried film 31 left behind in the PMOS region correspond to the “insulating layer” of the invention.

Among them, the supports 12 correspond to the “first insulating layer” of the invention, and the buried film 31 in the PMOS region corresponds to the “second insulating layer” of the invention.

What is claimed is:

1. A method for manufacturing a semiconductor device, comprising:
forming a first semiconductor layer on a semiconductor substrate;
forming a second semiconductor layer on the first semiconductor layer;
etching the second semiconductor layer and the first semiconductor layer to form a first groove passing through the second semiconductor layer and the first semiconductor layer;
forming a first support having tensile stress in the first groove;
etching the second semiconductor layer to form a second groove that exposes the first semiconductor layer;
forming a cavity between the second semiconductor layer and the semiconductor substrate by etching the first semiconductor layer through the second groove;
forming an insulating film in the cavity; and
forming a buried film having tensile stress in the second groove.

2. The method for manufacturing a semiconductor device according to claim 1, further comprising forming a first gate electrode on the second semiconductor layer with a first gate insulating film interposed therebetween.

3. A method for manufacturing a semiconductor device, comprising:
(a) forming a first semiconductor layer on a semiconductor substrate;
(b) forming a second semiconductor layer on the first semiconductor layer;
(c) etching the second semiconductor layer and the first semiconductor layer to form a first groove passing through the second semiconductor layer and the first semiconductor layer;
(d) forming a second support having compressive stress in the first groove;
(e) etching the second semiconductor layer to form a second groove that exposes the first semiconductor layer;
(f) forming a cavity between the second semiconductor layer and the semiconductor substrate by etching the first semiconductor layer through the second groove;
(g) forming an insulating film in the cavity; and
(h) forming a buried film having tensile stress in the second groove.

4. The method for manufacturing a semiconductor device according to claim 3, further comprising (i) forming a second gate electrode on the second semiconductor layer with a second gate insulating film interposed therebetween, wherein, in step (i), the second gate electrode is disposed such that a direction in which a force acts from the second support to the second semiconductor layer substantially coincides with a channel parallel direction and a direction in which a force acts from the buried film to the second semiconductor layer substantially coincides with a channel vertical direction.

5. A method for manufacturing a semiconductor device, comprising:
(a) forming a first semiconductor layer on a semiconductor substrate having a first region in which an NMOS transistor is to be formed and a second region in which a PMOS transistor is to be formed;
(b) forming a second semiconductor layer on the first semiconductor layer;
(c) etching the second semiconductor layer and the first semiconductor layer to form a first groove around the first region and around the second region, the first groove passing through the second semiconductor layer and the first semiconductor layer;
(d) forming a first support having tensile stress in the first groove formed around the first region;
(e) forming a second support having compressive stress in the first groove formed around the second region;
(f) etching the second semiconductor layer to form, around the first region and around the second region, a second groove that exposes the first semiconductor layer;
(g) forming a cavity between the second semiconductor layer in the first region and the second semiconductor layer and between the semiconductor substrate in the second region and the second semiconductor layer by etching the first semiconductor layer through the second groove;
(h) forming an insulating film in the cavity formed in the first region and in the cavity formed in the second region; and
(i) forming a buried film having tensile stress in the second groove formed around the first region and in the second groove formed around the second region.

6. The method for manufacturing a semiconductor device according to claim 5, further comprising:
(j) forming a first gate electrode on the second semiconductor layer in the first region with a first gate insulating film interposed therebetween; and
(k) forming a second gate electrode on the second semiconductor layer in the second region with a second gate insulating film interposed therebetween;
wherein in step (k), the second gate electrode is disposed such that a direction in which a force acts from the second support to the second semiconductor layer substantially coincides with a channel parallel direction and a direction in which a force acts from the buried film to the second semiconductor layer substantially coincides with a channel vertical direction.

7. The method for manufacturing a semiconductor device according to claim 3, the step (d) including:
forming a support film having tensile stress on the semiconductor substrate so as to fill the first groove; and
ion implanting an impurity into the support film.

8. A semiconductor device comprising:
a semiconductor substrate;
an insulating film formed on the semiconductor substrate;
a semiconductor layer formed on the insulating film; and
an insulating layer formed on the semiconductor substrate so as to surround the semiconductor layer in plan view, the insulating layer having tensile stress.

9. A semiconductor device comprising:
a semiconductor substrate;
an insulating film formed on the semiconductor substrate;
a semiconductor layer formed on the insulating film; and
an insulating layer formed on the semiconductor substrate so as to surround the semiconductor layer in plan view, the insulating layer including:
a first insulating layer disposed on sides before and after the semiconductor layer toward one direction in plan view, and
a second insulating layer disposed on sides before and after the semiconductor layer toward another direction substantially vertically intersecting the one direction in plan view;
wherein the first insulating layer has compressive stress and the second insulating layer has tensile stress.
